(19) United States
(12) Patent Application Publication
(10) Pub. No.: US 2013/0264568 A1
(43) Pub. Date: Oct. 10, 2013

(54) SEMICONDUCTOR DEVICE, COLOR FILTER SUBSTRATE, DISPLAY DEVICE PROVIDED WITH COLOR FILTER SUBSTRATE, AND METHOD FOR MANUFACTURING SEMICONDUCTOR DEVICE

(71) Applicants: Masahiro Tomida, Osaka (JP); Atsuyuki Hoshino, Osaka (JP)

(72) Inventors: Masahiro Tomida, Osaka (JP); Atsuyuki Hoshino, Osaka (JP)

(73) Assignee: SHARP KABUSHIKI KAISHA, Osaka (JP)

(21) Appl. No.: 13/994,630

(22) PCT Filed: Dec. 19, 2011
(86) PCT No.: PCT/JP2011/079380

§ 371 Date: Jun. 14, 2013

(30) Foreign Application Priority Data
Dec. 22, 2010 (JP) 2010-285678

(51) Int. Cl. H01L 29/786; H01L 29/66; G02B 5/20

(52) U.S. Cl. CPC H01L 29/7869; G02B 5/20; H01L 29/66742
USPC 257/43; 359/891; 438/104

(57) ABSTRACT

A purpose of the present invention is to provide: a semiconductor device where light-induced deterioration of characteristics of oxide semiconductor TFT is prevented without lowering the aperture ratio of pixels; a display device including such a semiconductor device; a color filter substrate; and a method for manufacturing such a semiconductor device. A semiconductor device (100A) of the present invention includes: a substrate (2); a thin film transistor (10) formed on the substrate (2); a light-absorbing film (15) that is formed on the thin film transistor (10) and that absorbs light having wavelengths of less than 450 nm; and a pixel electrode (17) connected to the thin film transistor (10). The thin film transistor (10) includes an oxide semiconductor layer (8). The light-absorbing film (15) is formed of an oxide containing In, Ga, or Zn. The light-absorbing film (15) is formed to overlap the thin film transistor (10) when viewed from normal direction to the semiconductor device (100A).

### TECHNICAL FIELD

The present invention relates to a semiconductor device having a thin film transistor (TFT) that includes an oxide semiconductor layer, and to a method for manufacturing the semiconductor device. Further, the present invention relates to a color filter substrate and to a display device equipped with the color filter substrate.

### BACKGROUND ART

In recent years, intense development of TFTs having an oxide semiconductor layer containing In (indium), Zn (zinc), Ga (gallium), or the like is underway (e.g. Patent Documents 1 to 3 and Non-Patent Documents 1 to 5). TFTs having an oxide semiconductor layer (hereinafter referred to as oxide semiconductor TFT) have high mobility characteristics.

Patent Document 1 discloses a liquid crystal display device where a chromatic color film is formed to cover an amorphous oxide semiconductor (a-IGZO) layer containing In, Ga, and Zn, to prevent light-induced deterioration of TFT characteristics. A color filter film and a black matrix (BM) film are described as examples of the chromatic color film. A substrate where a color filter film is formed thereon is called a color filter substrate. Generally, a color filter substrate has a BM film formed thereon.

### RELATED ART DOCUMENTS

### Patent Documents

Patent Document 1: Japanese Patent Application Laid-Open Publication No. 2010-152348
Patent Document 2: Japanese Patent Application Laid-Open Publication No. 2009-224354
Patent Document 3: Japanese Patent Application Laid-Open Publication No. 2007-150157

### Non-Patent Documents

Non-Patent Document 1: SID 08 DIGEST p. 1215-1218
Non-Patent Document 2: Journal of the Korean Physical Society, Vol. 53, No. 4, October 2008, pp. 2019-2023
Non-Patent Document 3: Japanese Journal of Applied Physics, Vol. 47, No. 8, 2008, pp. 6869-6899
Non-Patent Document 4: JOURNAL OF APPLIED PHYSICS 99, 124906 (2006)
Non-Patent Document 5: Journal of Information Display, Vol. 9, No. 4, December 2008

### SUMMARY OF THE INVENTION

### Problems to be Solved by the Invention

However, the inventors of the present invention found that, in the display device disclosed in Patent Document 1, even with a chromatic color film, depending on the light projected to the a-IGZOTFT, the TFT characteristics deteriorate (increased OFF current, negative threshold shift, and the like).

FIG. 8(a) is a graph showing the voltage-current characteristics of TFT when the a-IGZOTFT is driven in a dark condition, and when lights with different wavelengths are projected to the a-IGZOTFT. FIG. 8(b) is a graph showing the relationship between the stress time, i.e., the time during which lights of different colors are projected to the a-IGZOTFT, where the chromatic color films are red (R), blue (B), and green (G), and the difference in the threshold voltages of TFT (ΔVth). “D” of FIG. 8(b) is a curve representing the relationship between the time during which the a-IGZOTFT is driven in a dark condition (stress time) and the difference in the TFT threshold voltages (ΔVth). Here, ΔVth is the difference between the threshold voltage of TFT when the a-IGZOTFT is irradiated with lights of different colors (Vr) and the threshold voltage of TFT when the a-IGZOTFT is not irradiated with lights of different colors (Vn) (i.e., ΔVth=Vr−Vn).

As understood from FIG. 8(a), OFF current of TFT increases when lights of short wavelengths are projected to the a-IGZOTFT. Also, as understood from FIG. 8(b), the threshold voltages tend to shift to negative when lights R, G, and B are each projected to the a-IGZOTFT. The shift is particularly significant when light B is projected to the a-IGZOTFT.

If the chromatic color film is a BM film, the area over which the chromatic color film is provided cannot be large, because if the area is large, the pixel aperture ratio can be lowered. Therefore, depending on the light projection angle, the a-IGZO layer can be irradiated with light. As a result, deterioration of the TFT characteristics cannot be prevented sufficiently.

The present invention was devised in consideration of the issues described above, and is aiming at providing a semiconductor device that prevents the lowering of pixel aperture ratio and prevents the light-induced deterioration of the characteristics of the oxide semiconductor TFT, a display device having such a semiconductor device, a color filter substrate, and a method for manufacturing such a semiconductor device.

### Means for Solving the Problems

A semiconductor device according to an embodiment of the present invention includes: a substrate; a thin film transistor formed on the substrate; a light-absorbing film that is formed on the thin film transistor and that absorbs light with wavelengths of less than 450 nm; a pixel electrode connected to the thin film transistor, wherein the thin film transistor includes an oxide semiconductor layer, the light-absorbing film is formed of an oxide containing In, Ga, or Zn, and the light-absorbing film is formed to cover the thin film transistor when viewed from normal direction to the semiconductor device.

In an embodiment, the light-absorbing film is formed to cover the pixel electrode when viewed from normal direction to the semiconductor device.

In an embodiment, the light-absorbing film is formed of the same oxide of which the oxide semiconductor layer of the thin film transistor is formed.

In an embodiment, the oxide semiconductor layer contains In, Ga, or Zn.

In an embodiment, the light-absorbing film has a thickness of at least 0.1 μm and no greater than 10 μm.

A color filter substrate in an embodiment of the present invention is a substrate having a color filter formed thereon, including a light-absorbing film that absorbs light having wavelengths of less than 450 nm and that is provided on the substrate on the color filter side or on the substrate on the side opposite to the color filter side, wherein the light-absorbing film is formed of an oxide containing In, Ga, or Zn.

In an embodiment, the light-absorbing film has a thickness of at least 0.1 μm and no greater than 10 μm.

A display device according to an embodiment of the present invention includes the color filter substrate and a thin film transistor having an oxide semiconductor layer.

In an embodiment of the present embodiment, the light-absorbing film is formed of the same oxide of which the oxide semiconductor layer of the thin film transistor is formed.

A method for manufacturing a semiconductor device according to an embodiment of the present invention includes: a process (A) of preparing a substrate; a process (B) of forming on the substrate a thin film transistor having an oxide semiconductor layer; a process (C) of forming a light-absorbing film that absorbs light having wavelengths of less than 450 nm such that, when viewed from normal direction to the substrate, the light-absorbing film covers the thin film transistor.

In an embodiment, the process (C) includes a process (C1) of forming the light-absorbing film from the oxide film of which the oxide semiconductor layer of the thin film transistor is formed.

In an embodiment, the light-absorbing film is an oxide film containing In, Ga, or Zn.

In an embodiment, the process (C) includes a process (C2) of forming the light-absorbing film such that the light-absorbing film has a thickness of at least 0.1 μm and no greater than 10 μm.

In an embodiment, the process (C) includes a process (C3) of forming the light-absorbing film having insulating properties.

In an embodiment, the process (C) includes a process (C4) of forming the light-absorbing film having conductive properties.

### Effects of the Invention

The present invention provides: a semiconductor device, a color filter substrate, and a display device where light-induced deterioration of characteristics of the oxide semiconductor TFT is prevented without lowering the aperture ratio of pixels; and a method for manufacturing such a semiconductor device.

### BRIEF DESCRIPTION OF THE DRAWINGS

FIG. 1(a) is a schematic plan view of a liquid crystal display device 500A of an embodiment of the present invention. FIG. 1(b) is a schematic cross-sectional view of a semiconductor device 100A taken along the line I-I′ of FIG. 1(a). FIG. 1(c) is a schematic plan view of a semiconductor device 100A′ of another embodiment of the present invention.

FIG. 2(a) is a cross-sectional view schematically showing a liquid crystal display device 600. FIG. 2(b) is a cross-sectional view schematically showing the liquid crystal display device 500A. FIG. 2(c) is a graph showing the relationship between photon energies and the intensities of light entering a light-absorbing film 15 and of light that has passed through the light-absorbing film 15.

FIG. 3(a) is a graph showing the relationship between light wavelengths and transmittance of the light-absorbing films 15 having different thicknesses. FIG. 3(b) is a graph showing the relationship between the thickness and transmittance of the light-absorbing film 15, and the relationship between the thicknesses of the light-absorbing film 15 and the minimum OFF current values of TFT.

FIG. 4(a) is a graph showing the relationship between light wavelengths and transmittance of a-IGZO films deposited with different oxygen concentrations. FIG. 4(b) is a graph showing the case where the light-absorbing film 15 is an a-IZO film, illustrating the relationship between light wavelengths and transmittance of a-IZO films deposited with different oxygen concentrations. FIG. 4(c) is a graph showing the case where the light-absorbing film 15 is an a-ZnO film, illustrating the relationship between light wavelengths and transmittance.

FIG. 5(a) to FIG. 5(e) are cross-sectional views illustrating a manufacturing process of the semiconductor device 100A.

FIG. 6(a) is a schematic plan view of a liquid crystal display device 500B according to another embodiment of the present invention. FIG. 6(b) is a schematic cross-sectional view of the liquid crystal display device 500B taken along the line II-II′ of FIG. 6(a).

FIG. 7(a) is a schematic plan view of a liquid crystal display device 500C according to yet another embodiment of the present invention. FIG. 7(b) is a schematic cross-sectional view of the liquid crystal display device 500C taken along the line III-III′ of FIG. 7(a).

FIG. 8(a) is a graph showing the current-voltage characteristics of TFT when lights of different wavelengths are projected to the a-IGZOTFT. FIG. 8(b) is a graph showing the relationship between the time during which lights of different colors are projected to the a-IGZOTFT (Stress Time) and the difference in the threshold voltages (ΔVth).

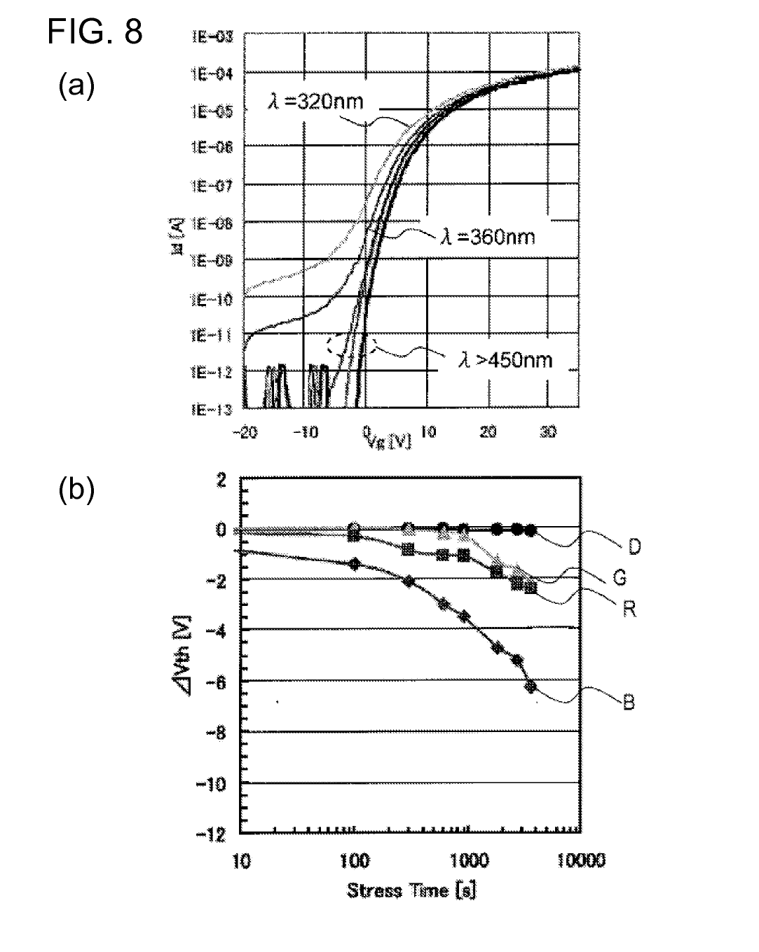

### DETAILED DESCRIPTION OF EMBODIMENTS

With reference to figures, a semiconductor device according to embodiments of the present invention, a display device having the semiconductor device (a liquid crystal display device in the present embodiments), and a method for manufacturing such a semiconductor device are described. The present invention, however, is not limited to embodiments described as examples.

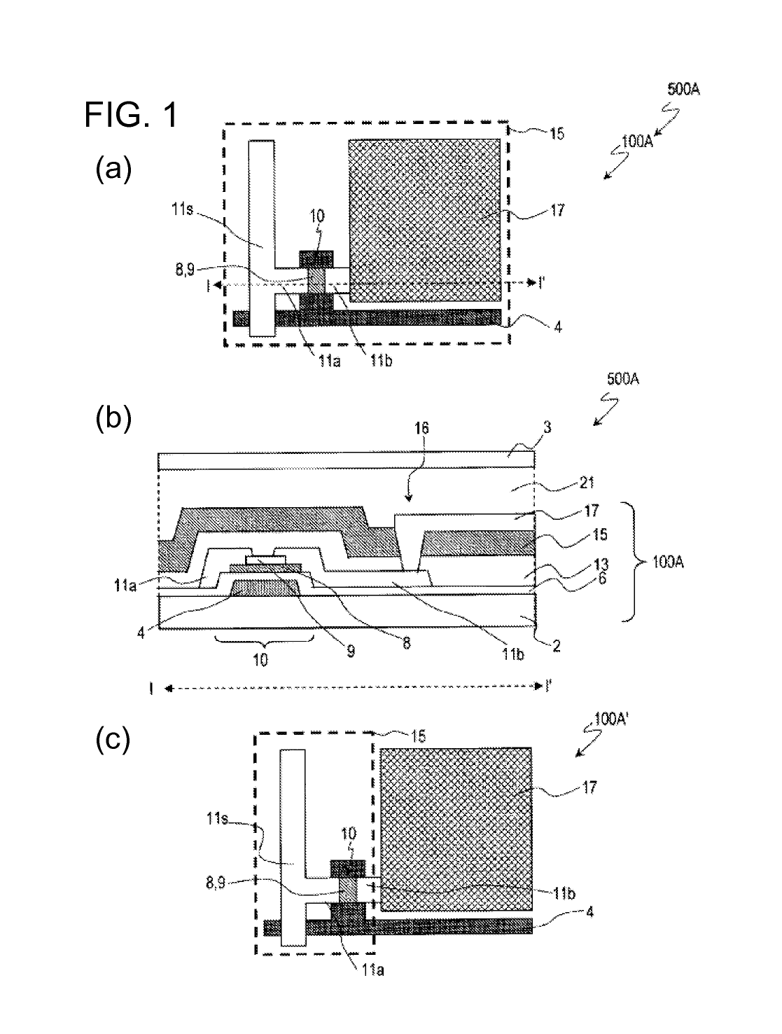

FIG. 1(a) is a schematic plan view of a liquid crystal display device 500A, which includes a semiconductor device 100A of an embodiment of the present invention. FIG. 1(b) is a schematic cross-sectional view of the semiconductor device 100A, taken along the line I-I′ of FIG. 1(a). FIG. 1(c) is a schematic plan view of a semiconductor device 100A′ of another embodiment of the present invention.

As shown in FIG. 1(a) and FIG. 1(b), a liquid crystal display device 500A includes: a semiconductor device 100A having a first substrate (e.g. glass substrate) 2; a liquid crystal layer 21; and a second substrate (e.g. glass substrate) 3. The liquid crystal layer 21 is formed between the first substrate 2 and the second substrate 3. The semiconductor device 100A includes a TFT 10 formed on the first substrate 2. TFT 10 includes a gate electrode 4 and a gate insulating film 6 formed on the gate electrode 4. Further, TFT 10 includes an oxide semiconductor layer 8 formed on the insulating film 6, and an etch stopper layer 9 formed on the oxide semiconductor layer 8. In this embodiment, the oxide semiconductor layer 8 is an a-IGZO layer. In some cases, the etch stopper layer 9 is not formed. Further, TFT 10 includes a source electrode 11a and a drain electrode 11b formed over the oxide semiconductor layer 8. Further, the semiconductor device 100A includes a protective film 13 formed over the source electrode 11a and the drain electrode 11b, and a light-absorbing film 15 formed on the protective film 13. In this embodiment, the light-absorbing film 15 is an a-IGZO film. Further, the semiconductor device 100A includes a pixel electrode 17 electrically connected to the drain electrode 11b through a contact hole 16. On the pixel electrode 17, an alignment film (not shown) is formed on the side facing the liquid crystal layer 21.

An opposite electrode (not shown) is formed on the second substrate 3 on the side facing the liquid crystal layer 21, and an alignment film (not shown) is formed on the opposite electrode on the side facing the liquid crystal layer 21.

As shown in FIG. 1(a), the light-absorbing film 15 is formed to cover the entire surface of the first substrate 2 (excluding the area that will be a contact hole 16). The light-absorbing film 15 absorbs lights having wavelengths of less than 450 nm (may be referred to as short wavelengths), and transmits visible lights of other wavelengths.

As in this embodiment, if the light-absorbing film 15 is formed of amorphous oxide film, the potential of the oxide semiconductor layer 8 can increase due to, for example, the coupling capacitance between a source wiring 11s, which is electrically connected to a source electrode 11a, and the light-absorbing film 15. However, the increase in the potential can be prevented by fixing the potential of the light-absorbing film 15 (to 0V, for example).

This way, with the light-absorbing film 15 included in the semiconductor device 100A, light-induced deterioration of TFT 10 characteristics can be prevented. Especially, if the light-absorbing film 15 is formed of an amorphous oxide film containing the same material of which the oxide semiconductor layer 8 of TFT 10 is formed, the light-absorbing film 15 absorbs lights of short-wavelengths. As a result, light-induced deterioration of characteristics of TFT 10 can be prevented. This is discussed in detail below. If the light-absorbing film 15 is formed of an amorphous oxide film containing the same material of which the oxide semiconductor layer 8 is formed, lights that affect the TFT characteristics are absorbed by the light-absorbing film 15. Consequently, the lights that have passed through the light-absorbing film 15 do not contain the components that affect the TFT characteristics. Further, because the light-absorbing film 15 formed of the amorphous oxide film is semi-transparent to lights having wavelengths of greater than 450 nm and no greater than 830 nm, the aperture ratio of pixels is not reduced.

Also, as shown in FIG. 1(c), a light-absorbing film 15 that is not in contact with the pixel electrode 17 may be formed to cover TFT 10. When viewed from normal direction to a semiconductor device 100A′, the light-absorbing film 15 is formed to overlap TFT 10. If the light-absorbing film 15 is formed such that it does not touch the pixel electrode 17, the light-absorbing film 15, even if it is a conductor (or semiconductor), is not electrically connected to the pixel electrode 17. Therefore, the potential of oxide semiconductor layer 8 does not rise, and, consequently, no leakage current flows into TFT 10. Also, in the case that the light-absorbing film 15 is an insulator, the light-absorbing film 15 is not electrically connected to the pixel electrode 17 even if the pixel electrode 17 touches the light-absorbing film 15. The potential of the oxide semiconductor layer 8, therefore, does not rise, and no leakage current flows into TFT 10.

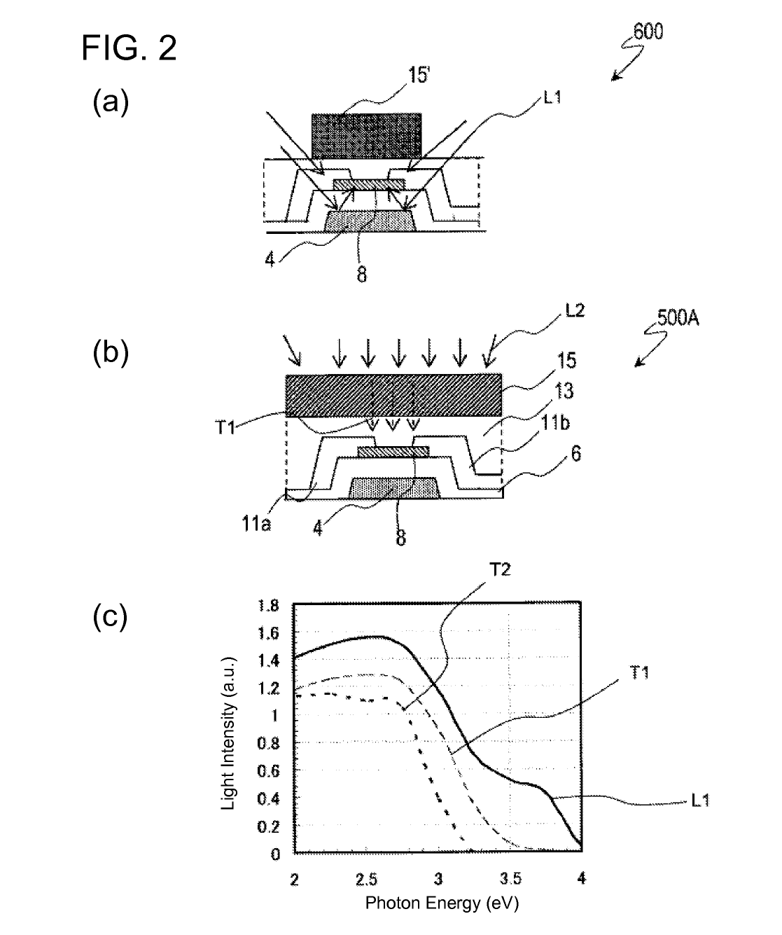

Next, with reference to FIG. 2, the effect of a liquid crystal display device 500 is described in comparison with a liquid crystal display device 600 disclosed in Patent Document 1.

As shown in FIG. 2(a), the liquid crystal display device 600 disclosed in Patent Document 1 includes a black resin layer 15′ instead of the above-mentioned light-absorbing film 15, such that it covers the oxide semiconductor layer 8. The black resin layer 15′ is formed such that the aperture ratio of pixels will not be lowered. As a result, the black resin layer 15′ cannot absorb light L1, which has a wavelength of less than 450 nm and which enters the liquid crystal display device 600 from an angle. Consequently, the oxide semiconductor layer 8 is irradiated with light L1, and characteristics of the TFT that includes the oxide semiconductor layer 8 can be deteriorated. On the other hand, in the liquid crystal display device 500A shown in FIG. 2(b), as described above, the light-absorbing film 15 is formed to cover a large area including the oxide semiconductor layer 8. Therefore, light L2, which has a wavelength of less than 450 nm and enters the liquid crystal display device 500A, is absorbed by the light-absorbing film 15 no matter which direction it comes from. This way, deterioration of TFT characteristics is prevented.

FIG. 2(c) is a graph illustrating the relationship between the photon energy and the intensity of the light L1 entering the light-absorbing film 15, and lights T1 and T2, which have passed through the light-absorbing film 15. In FIG. 2(c), the light-absorbing film 15 is an a-IGZO film, where the element ratio is In:Zn:Ga=1:1:1. “L1” denotes a photon energy-light intensity curve when the sunlight AM (air mass) is 1.5 (external light). “T1” denotes a photon energy-light intensity curve of the light that has passed through the light-absorbing film 15 having a thickness of 1 μm, and “T2” denotes a photon energy-light intensity curve of the light that has passed through the light-absorbing film 15 having a thickness of 10 μm.

As shown in FIG. 2(c), of lights T1 and T2, which have entered the light-absorbing film 15 and have passed through the light-absorbing film 15, lights with photon energies higher than 2.76 eV are absorbed. Also, the thicker the light-absorbing film 15, the greater the absorbance of the light-absorbing film 15.

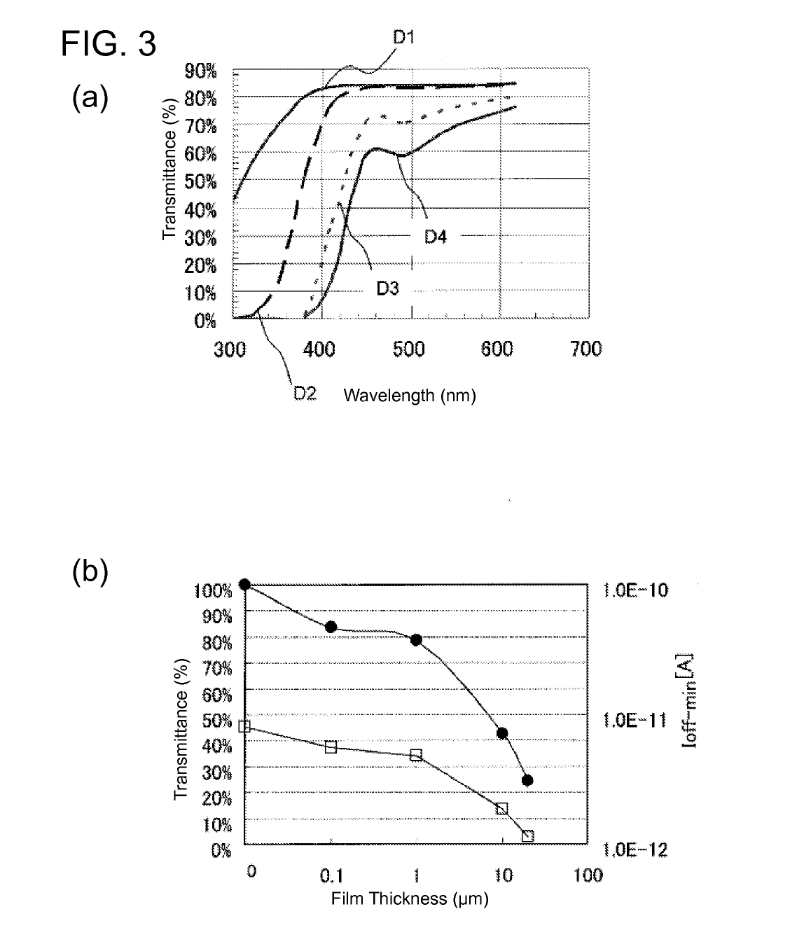

FIG. 3(a) is a graph illustrating the relationship between light wavelengths and transmittance by an a-IGZO (element ratio; In:Ga:Zn=1:1:1) film. “D1” of FIG. 3(a) is a light wavelength-transmittance curve when the a-IGZO film is 0.1 μm thick. “D2” is a light wavelength-transmittance curve when the a-IGZO film is 1 μm thick. “D3” is a light wavelength-transmittance curve when the a-IGZO film is 10 μm thick. “D4” is a light wavelength-transmittance curve when the a-IGZO film is 20 μm thick. All the a-IGZO films absorb lights of less than 450 nm relatively strongly than lights of 450 nm or higher. The a-IGZO films, therefore, can suppress the light-induced deterioration of TFT characteristics without affecting the light intensity that contributes to the display. When the a-IGZO film is 0.1 μm thick, absorbance of light with a wavelength of about 450 nm is about 16%, and absorbance of light with a wavelength of about 300 nm is about 56%. When the a-IGZO film is 1 μm thick, absorbance of light with a wavelength of about 450 nm is about 17%, and absorbance of light with a wavelength of about 300 nm is about 100%. When the a-IGZO film is 10 μm thick, absorbance of light with a wavelength of about 450 nm is about 28%, and absorbance of light with a wavelength of about 300 nm is about 100%. The thicker the a-IGZO film, the greater the absorbance of lights with a wavelengths of less than 450 nm.

FIG. 3(b) is a graph illustrating the relationship between the film thickness of the light-absorbing film 15 and the minimum value of OFF current of TFT 10 included in the semiconductor device 100A when the light-absorbing film 15 is an a-IGZO (element ratio; In:Ga:Zn=1:1:1) film, and also the relationship between the film thickness of the light-absorbing film 15 and the transmittance of light with a wavelength of 420 nm. In FIG. 3(b), the curve indicated by dark dots () represents the relationship between the film thickness of the light-absorbing film 15 and transmittance by the light-absorbing film 15, and the curve indicated by squares (□) represents the relationship between the film thickness of the light-absorbing film 15 and the minimum OFF current value of TFT.

When light with a wavelength of 420 nm is projected to the oxide semiconductor layer 8, the minimum OFF current value of TFT is about 1.0×10⁻¹¹ A. By forming the light-absorbing film 15 such that it covers the oxide semiconductor layer 8 when viewed from normal direction to the semiconductor device, and by increasing the film thickness of the light-absorbing film 15, the minimum OFF current value of TFT gradually decreases. When the film thickness of the light-absorbing film 15 is 0.1 μm or greater, light with a wavelength of 420 nm is absorbed, and the minimum OFF current of TFT decreases. In particular, when the film thickness of the light-absorbing film 15 is 1 μm or greater, absorbance of light with a wavelength of 420 nm by the light-absorbing film 15 increases, and the minimum OFF current value of TFT lowers to about 1.0×10⁻¹² A. On the other hand, when film thickness of the light-absorbing film 15 exceeds 10 μm, blue display is affected. Consequently, film thickness of the light-absorbing film 15 is preferably at least 0.1 μm and no greater than 10 μm, and more preferably, at least 1 μm and no greater than 10 μm.

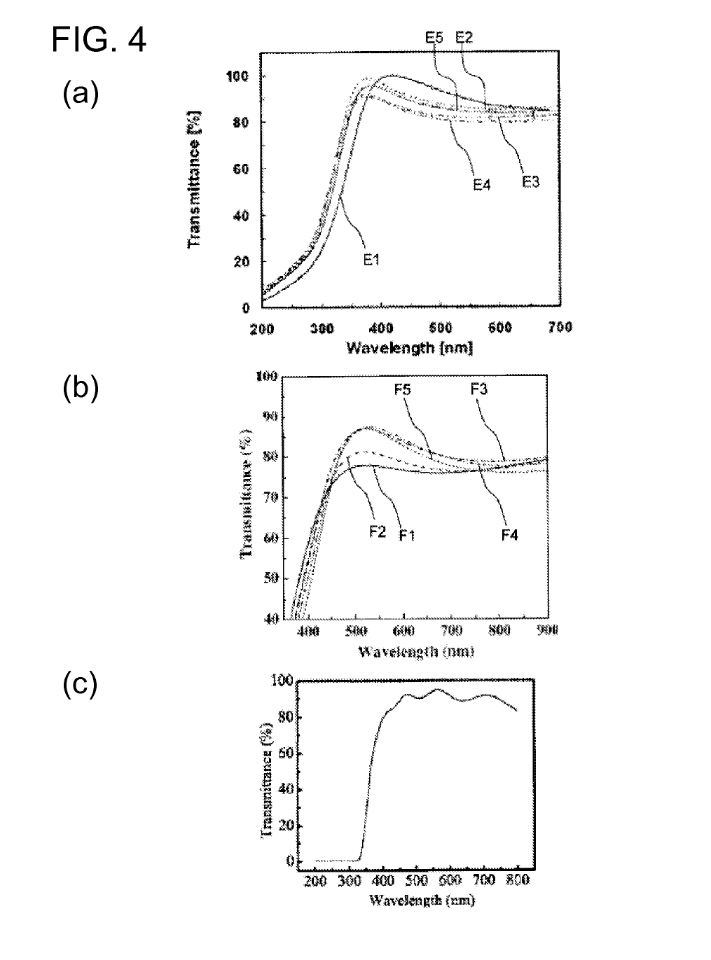

Next, relationship between the concentration of oxygen used for depositing the a-IGZO film and absorbance of the a-IGZO film is described with reference to FIG. 4(a).

FIG. 4(a) is a graph illustrating the relationship between light wavelengths and transmittance by an a-IGZO (element ratio; In:Ga:Zn=1:1:1) film having a film thickness of 100 nm. When depositing the a-IGZO film, O₂ (oxygen) and Ar (argon) are used. In FIG. 4(a), E1 is a curve of light wavelength-transmittance when the oxygen concentration for depositing the light-absorbing film 15 is 0%. E2 is a curve of light wavelength-transmittance when the oxygen concentration for depositing the light-absorbing film 15 is 10%. E3 is a curve of light wavelength-transmittance when the oxygen concentration for depositing the light-absorbing film 15 is 20%. E4 is a curve of light wavelength-transmittance when the oxygen concentration for depositing the light-absorbing film 15 is 30%. E5 is a curve of light wavelength-transmittance when the oxygen concentration for depositing the light-absorbing film 15 is 40%.

As understood from FIG. 4(a), transmittance of lights with different wavelengths by the a-IGZO film changes depending on the oxygen concentration used for depositing, even if the composition ratio of In, Ga, and Zn and the film thickness are the same. Table 1 shows optical bandgaps of a-IGZO films deposited with different oxygen concentrations.

TABLE 1

| | Oxygen Concentrations | | | | |
|---|---|---|---|---|---|
| | [O₂/(Ar + O₂)] (%) | | | | |
| | 0 | 10 | 20 | 30 | 40 |
| Bandgaps (eV) | 3.04 | 3.29 | 3.26 | 3.23 | 3.22 |

As understood from Table 1, the optical bandgap increases when higher oxygen concentrations are used for depositing. Therefore, the a-IGZO film acquires insulating properties if deposited using high oxygen concentrations. However, even if the a-IGZO film acquires insulating properties, the optical bandgap of the a-IGZO film does not significantly change. When an a-IGZO film is used as the light-absorbing film 15, the light-absorbing film 15 may be a conductor, semi-conductor, or insulator. The film thickness of the light-absorbing film 15 and the oxygen concentration for depositing can be adjusted appropriately for efficient absorption of lights with wavelengths of choice.

The case where the light-absorbing film 15 is an a-IGZO film is described above with reference to FIGS. 2(b), 3(a), 3(b), and 4(a). Cases where the light-absorbing film 15 is an a-IZO film or an a-ZnO film are described with reference to FIGS. 4(b) and 4(c). The a-IZO film is an amorphous oxide semiconductor film that contains In and Zn, but does not contain Ga. The a-ZnO film is an amorphous oxide semiconductor film that contains Zn, but does not contain In or Ga.

FIGS. 4(b) and 4(c) are graphs illustrating the relationship between the light wavelengths and transmittance of the a-IZO film and the a-ZnO film, respectively.

FIG. 4(b) is a graph illustrating the relationship between the light wavelengths and transmittance of the a-IZO film when the film thickness is 125 nm (mass ratio at the target; In₂O₃:ZnO=9:1). F1 of FIG. 4(b) is a light wavelength-transmittance curve of an a-IZO film deposited using air instead of O₂ and Ar. F2 is a light wavelength-transmittance curve of an a-IZO film deposited with an oxygen concentration of 0.2%. F3 is a light wavelength-transmittance curve of an a-IZO film deposited with an oxygen concentration of 0.4%. F4 is a light wavelength-transmittance curve of an a-IZO film deposited with an oxygen concentration of 0.6%. F5 is a light wavelength-transmittance curve of an a-IZO film deposited with an oxygen concentration of 0.8%. Regardless of the deposition condition, the a-IZO film absorbs lights with wavelengths of less than 450 nm relatively strongly than lights with wavelengths of 450 nm or greater.

FIG. 4(c) is a graph illustrating the relationship between the light wavelengths and transmittance of an a-ZnO film that has a film thickness of 430 nm and that is doped with 5% (mass concentration) Al (aluminum). The a-ZnO film also absorbs light with a wavelength of less than 450 nm relatively strongly than light of 450 nm or greater wavelength.

Similar to the a-IGZO film, whether the light-absorbing film 15 is an a-IZO film or an a-ZnO film, the film thickness is preferably at least 0.1 μm and no greater than 10 μm, and more preferably at least 1 μm and no greater than 10 μm.

As described above, preferably the light-absorbing film 15 has characteristics that absorb lights with short wavelengths (wavelengths of less than 450 nm) and that transmit visible lights with other wavelengths. Also, the light-absorbing film 15 may be formed of a material that is different from the material of which the oxide semiconductor layer 8 of TFT 10 is formed. In this case, however, designs of the light-absorbing film 15 need to be studied separately. Specifically, materials are selected and designing is conducted (for example, composition of a compound is determined) such that the light-absorbing film 15 acquires the same light absorption characteristics as the oxide semiconductor layer 8 (absorption characteristics for wavelengths of less than 450 nm), and then a sample is prepared and tested. The light-absorbing film 15 may be a semiconductor film, conductive film, or insulating film.

Next, individual constituting elements of the semiconductor device 100A are described.

A gate electrode 4, a source wiring line 11s, a source electrode 11a, and a drain electrode 11b have a multi-layer structure constituted of, for example, an Al (aluminum) upper layer and a Ti (titanium) lower layer. The upper layer may alternatively be a Cu (copper) layer instead of an Al layer. The gate electrode 4, the source wiring line 11s, the source electrode 11a, and the drain electrode 11b may alternatively have a mono-layer structure made of a Ti, Mo (molybdenum), Ta (tantalum), or Cr (chrome) layer. The thicknesses of the gate electrode 4, source wiring line 11s, source electrode 11a, and drain electrode 11b are at least 100 nm and no greater than 300 nm, for example.

A gate insulating film 6, an etch stopper layer 9, and a protective film 13 are formed of SiO₂ (silicon dioxide), for example. They may alternatively be formed of SiNx (silicon nitride). The gate insulating film 6, the etch stopper layer 9, and the protective film 13 may alternatively have a multi-layer structure containing SiO₂ and SiNx. Further, in some cases, a photosensitive organic insulating film may be formed on the protective film 13. The thickness of the gate insulating film 6 is at least 300 nm and no greater than 400 nm, for example. The thickness of the etch stopper layer 9 is at least 100 nm and no greater than 200 nm, for example. The thickness of the protective film 13 is at least 200 nm and no greater than 300 nm, for example.

An oxide semiconductor layer 8 is an a-IGZO layer, for example. The oxide semiconductor layer 8 may alternatively be an a-IZO layer or an a-ZnO layer, for example. The thickness of the oxide semiconductor layer 8 is at least 40 nm and no greater than 50 nm, for example.

A light-absorbing film 15 is an a-IGZO film. The light-absorbing film 15 may alternatively be an a-IZO film or an a-ZnO film. As described above, the light-absorbing film 15 is preferably formed of a film containing the same material of which the oxide semiconductor layer of TFT 10 is formed. The thickness of the light-absorbing film 15 is preferably at least 0.1 μm and no greater than 10 μm, and more preferably at least 1 μm and no greater than 10 μm, for example. This is because the light is not sufficiently absorbed when the thickness is less than 0.1 μm, and the blue display is affected when the thickness exceeds 10 μm.

A pixel electrode 17 is a transparent electrode formed of, for example, ITO (Indium Tin Oxide). The pixel electrode 17 is not, however, limited to this.

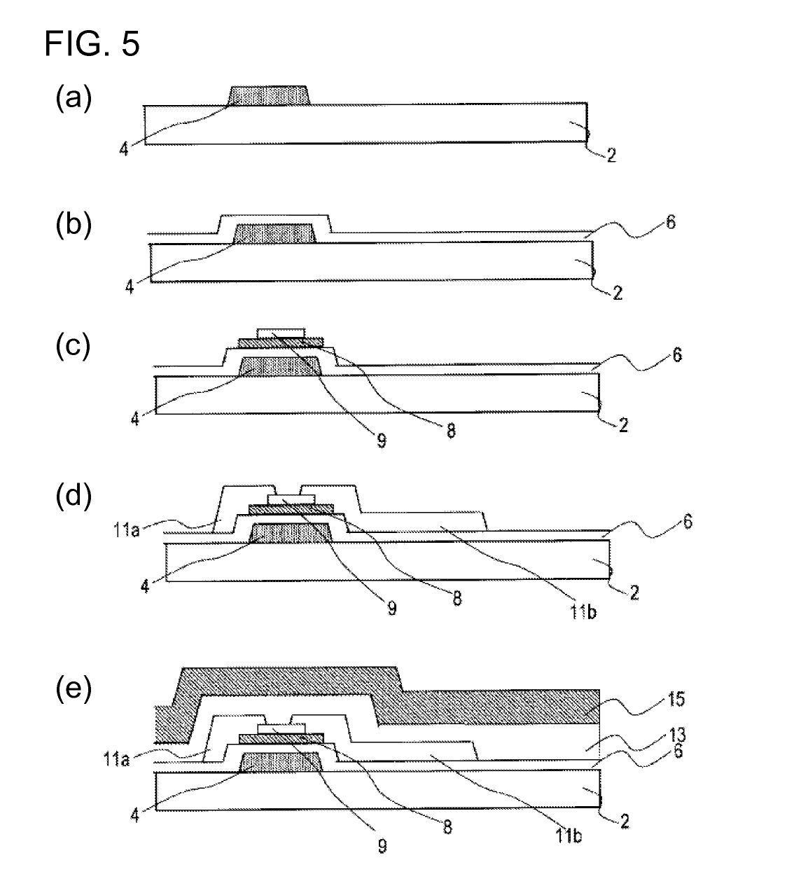

Next, with reference to FIG. 5, a method for manufacturing the semiconductor device 100A is described. FIG. 5 shows cross-sectional views illustrating the method for manufacturing the semiconductor device 100A.

As shown in FIG. 5(a), on a first substrate 2, using the sputtering method, a first conductive film (not shown) having a multi-layer structure including an upper Al layer and a lower Ti layer, for example, is deposited. Then, using a known method, the first conductive film is patterned to form the gate electrode 4. The thickness of the first conductive film is at least 100 nm and no greater than 300 nm, for example. The first conductive film may alternatively have a Cu layer instead of an Al layer. The first conductive film may alternatively have a monolayer structure formed of a Ti, Mo, Ta, or Cr layer.

Next, as shown in FIG. 5(b), using the plasma CVD (Chemical Vapor Deposition) method, a gate insulating film 6 containing SiO₂ is deposited on the gate electrode 4 at a temperature of 300 to 400° C. The gate insulating film 6 may alternatively be formed of SiNx, and may alternatively have a multi-layer structure of SiO₂ and SiNx. The thickness of the gate insulating film 6 is at least 300 nm and no greater than 400 nm, for example.

Next, as shown in FIG. 5(c), using the sputtering method, an amorphous oxide semiconductor film is deposited on the gate insulating film 6 at 200 to 400° C. Then, using a known method, the amorphous oxide semiconductor film is patterned to form an oxide semiconductor layer 8. The amorphous oxide semiconductor film is an a-IGZO film. The amorphous oxide semiconductor film may alternatively be an a-IZO film or an a-ZnO film. The thickness of the amorphous oxide semiconductor film is at least 40 nm and no greater than 50 nm, for example. The amorphous oxide semiconductor film may alternatively be formed by the coating process instead of the sputtering method.

Next, using the plasma CVD method, a first insulating film (not shown) containing SiO₂ is formed on the oxide semiconductor layer 8 at a temperature of 300 to 400° C. Then, with a known method, the first insulating film is patterned to form the etch stopper layer 9. By forming the etch stopper layer 9, the oxide semiconductor layer 8 can be protected from being etched when the dry etching is conducted later to form a source electrode 11a and a drain electrode 11b. If there is enough etching selectivity between the oxide semiconductor layer 8, and the source electrode 11a and the drain electrode 11b, which are described below, neither the first insulating film nor the etch stopper layer 9 need not to be formed. The first insulating film may alternatively be formed of SiNx, and may alternatively have a multi-layer structure containing SiO₂ and SiNx. The thickness of the first insulating film is at least 100 nm and no greater than 200 nm, for example.

Next, as shown in FIG. 5(d), using the sputtering method, a second conductive film (not shown) having, for example, an Al upper layer and a Ti lower layer is deposited on the oxide semiconductor layer 8. The second conductive film is patterned with a known method to form the source electrode 11a and the drain electrode 11b. The upper layer may alternatively be a Cu layer instead of an Al layer. The second conductive film may alternatively have a mono-layer structure formed of a Ti, Mo, Ta, or Cr film. The thickness of the second conductive film is at least 100 nm and no greater than 300 nm, for example.

Next, as shown in FIG. 5(e), using the plasma CVD method, a protective film 13 containing SiO₂ is deposited over the source electrode 11a and the drain electrode 11b at a temperature of 200 to 300° C. to cover the entire surface of the first substrate 2. The protective film 13 may alternatively be formed of SiNx, and may alternatively have a multi-layer structure of SiO₂ and SiNx. The thickness of the protective film 13 is at least 200 nm and no greater than 300 nm, for example.

Next, using the sputtering method, a light-absorbing film 15, which is formed of an amorphous oxide film of which the oxide semiconductor layer 8 is formed (a-IGZO layer, for example), is formed on the protective film 13 to cover the entire surface of the first substrate 2. As described above, the light-absorbing film 15 is preferably an amorphous oxide film containing the same material of which the oxide semiconductor layer 8 is formed. However, the light-absorbing film 15 may alternatively be an amorphous oxide film that is different from the amorphous oxide film of which the oxide semiconductor layer 8 is formed (an a-IZO film or an a-ZnO film, for example). The light-absorbing film 15 may be deposited by a coating process, instead of the sputtering method. The thickness of the light-absorbing film 15 is at least 0.1 μm and no greater than 10 μm. If the light-absorbing film 15 is conductive, and if a pixel electrode 17, which is described below, and the light-absorbing film 15 touch each other, the potential of the light-absorbing film 15 increases and a leakage current might flow to TFT 10. If the light-absorbing film 15 is a conductor or a semiconductor, the light-absorbing film 15 is preferably patterned such that the light-absorbing film 15 and the pixel electrode 17 will not touch each other (see FIG. 1(c)). Further, although the potential at the oxide semiconductor layer 8 can increase due to the capacitance coupling of the source wiring line 11s and the light-absorbing film 15, by fixing the potential at the light-absorbing film 15 to 0V, for example, rising of the potential at the oxide semiconductor layer 8 can be prevented. For the deposition of the light-absorbing film 15, the light-absorbing film 15 may alternatively be deposited under the condition that makes the light-absorbing film 15 an insulating film (for example, the oxygen flow ratio is increased when the light-absorbing film 15 is deposited with the sputtering method, such that, specifically, the flow ratio of O₂ (oxygen)/Ar (argon) is at least 0.4, for example). If the light-absorbing film 15 is to be a film other than the amorphous oxide film containing the same material of which the oxide semiconductor layer 8 is formed, the process of forming the light-absorbing film 15 needs to be studied separately. Specifically, materials are selected and designing is conducted (determination of composition of a compound, for example) such that the light-absorbing film 15 acquires the same light absorption characteristics as the oxide semiconductor layer 8 (absorption characteristics for wavelengths of less than 450 nm), for example, and further, the deposition method and deposition conditions for the light-absorbing film 15 are optimized.

Next, a heat treatment (annealing treatment) is conducted for 1 to 2 hours in a dry air atmosphere at 200° C. to 400° C. At this time, especially if the operating voltage of TFT 10 is −30V to +30V, from the result of the device simulation, the carrier concentration of the oxide semiconductor layer 8 is preferably at least 1×10¹⁶ cm³ and no greater than 1×10¹⁸ cm³. If the operating voltage of TFT 10 falls within a range narrower than −30V to +30V range, the carrier concentration of the oxide semiconductor layer 8 is preferably within a range narrower than the 1×10¹⁶ cm³ to 1×10¹⁸ cm³ range.

Next, a contact hole 16 connecting to the drain electrode 11b is formed through the protective film 13 and the light-absorbing film 15 (see FIG. 1(b)). Subsequently, a third conductive film (not shown) is deposited on the light-absorbing film 15 with a known method, and the third conductive film is patterned with a known method to form a pixel electrode 17 such that the pixel electrode 17 is electrically connected to the drain electrode 11b. This way, the semiconductor device 100A is obtained. The third conductive film is formed, for example, of ITO. The thickness of the third conductive film is at least 50 nm and no greater than 100 nm, for example.

Then, with a known method, a liquid crystal display device 500A is obtained.

Next, liquid crystal display devices 500B and 500C according to other embodiments of the present invention, having the same effect as the semiconductor device 500A described above, are described. For common constituting elements, same reference characters are used and redundant explanations are avoided.

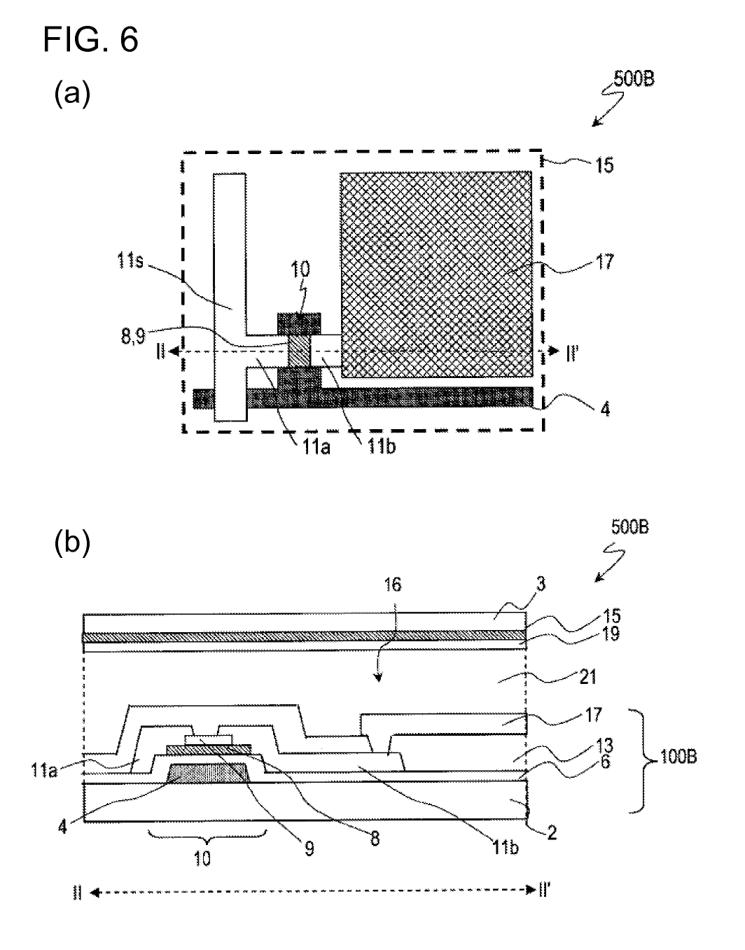

First, the liquid crystal display device 500B is described with reference to FIG. 6. FIG. 6(a) is a schematic plan view of the liquid crystal display device 500B, and FIG. 6(b) is a schematic cross-sectional view of the liquid crystal display device 500B taken along the line II-II′ of FIG. 6(a).

The liquid crystal display device 500B shown in FIGS. 6(a) and 6(b) includes: a semiconductor device 100B, which has everything that the semiconductor device 100A has, except for the light-absorbing film 15; a second substrate 3; and a liquid crystal layer 21 positioned between the first substrate 2 and the second substrate 3. The second substrate 3 includes a light-absorbing film 15 formed over the entire surface of the second substrate 3 on the side facing the liquid crystal layer 21, and an opposite electrode 19 formed on the liquid crystal layer 21 side of the light-absorbing film 15. If the light-absorbing film 15 is a conductor, for example, in some cases, the opposite electrode 19 does not need to be formed. The opposite electrode 19 is formed of ITO, for example. The thickness of the opposite electrode 19 is at least 50 nm and no greater than 100 nm, for example.

The liquid crystal display device 500B, which is configured as described above, has the same effect as the above-mentioned liquid crystal display device 500A.

Next, a method for manufacturing the liquid crystal display device 500B is described.

A semiconductor device 100B is manufactured almost in the same manner as the above-mentioned semiconductor device 100A. The light-absorbing film 15, however, is not formed in the semiconductor device 100B.

A color filter layer (not shown) is formed on the second substrate 3. On the color filter layer, a light-absorbing film 15 is formed with the method described above. If the light-absorbing film 15 is to be formed as a conductor, when the light-absorbing film (a-IGZO film, for example) 15 is formed using the sputtering method, the oxygen flow ratio is lowered (O₂/Ar flow ratio is no greater than 0.01, for example) to deposit the light-absorbing film 15.

Next, using a known method, an opposite electrode 19 is formed on the light-absorbing film 15. The opposite electrode 19 is formed of ITO, for example. The thickness of the opposite electrode 19 is at least 50 nm and no greater than 100 nm, for example. If the light-absorbing film 15 is to be a conductor, for example, in some cases, the opposite electrode 19 does not have to be formed.

Next, the first substrate 2 of the semiconductor device 100B and the second substrate 3 over which the light-absorbing film 15 has been formed are bonded together using a known method such that the pixel electrode 17 and the opposite electrode 19 face each other. A liquid crystal layer 21 is then formed with the vacuum injection method, for example. The liquid crystal layer 21 can alternatively be formed with the ODF (One Drop Filling) method. Subsequently, with a known method, a liquid crystal display device 500B is obtained.

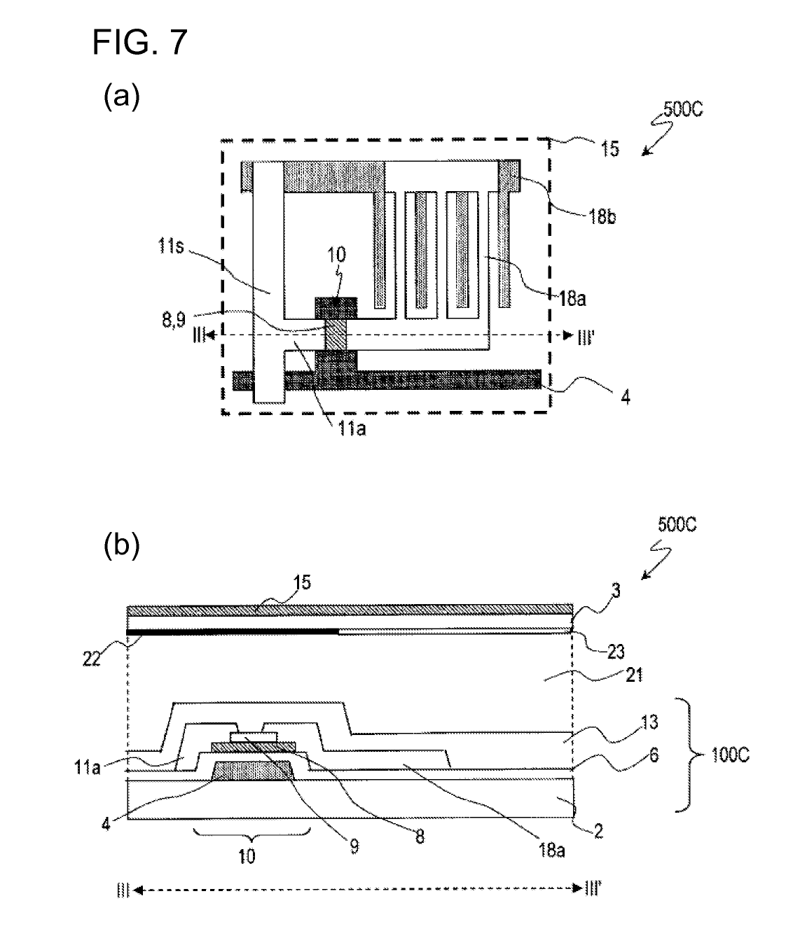

Next, a liquid crystal display device 500C is described with reference to FIG. 7. FIG. 7(a) is a schematic plan view of the liquid crystal display device 500C, and FIG. 7(b) is a schematic cross-sectional view of the liquid crystal display device 500C taken along the line III-III′ of FIG. 7(a).

The liquid crystal display device 500C is an IPS (In-Plane Switching) system (or FFS (Fringe Field Switching) system) liquid crystal display device.

As shown in FIGS. 7(a) and 7(b), the liquid crystal display device 500C includes: a semiconductor device 100C having a first substrate 2; a liquid crystal layer 21; and a second substrate 3. A liquid crystal layer 21 is formed between the first substrate 2 and the second substrate 3. The semiconductor device 100C includes a pixel electrode 18a electrically connected to the drain electrode 11b of the semiconductor device 100A (see FIG. 1(b)). Also, the semiconductor device 100C includes an opposite electrode 18b, which faces the pixel electrode 18a. A transverse electric field is generated in the liquid crystal layer 21 by the pixel electrode 18a and the opposite electrode 18b to drive the liquid crystal layer 21. The pixel electrode 18a and the opposite electrode 18b are formed of ITO, for example. The pixel electrode 18a and the opposite electrode 18b can also be formed of Al, for example.

The second substrate 3 has a light-shielding layer 22 and a color filter layer 23 formed on the liquid crystal layer 21 side. However, in the liquid crystal display device 500C, unlike the liquid crystal display device 500B, the opposite electrode 19 (see FIG. 6(b)) made of ITO is not formed on the second substrate 3. Further, the above-mentioned light-absorbing film 15 is formed on the second substrate 3 on the side opposite to the liquid crystal layer 21. The light-absorbing film 15 is formed over the entire surface of the second substrate 3. If the light-absorbing film 15 is an insulator, like the semiconductor device 100A or 100A′, the light-absorbing film 15 may be formed in the semiconductor device 100C, and further, like the liquid crystal display device 500B, the light-absorbing film 15 may be formed on the second substrate 3 on the liquid crystal layer 21 side. If the light-absorbing film 15 is a conductor or a semiconductor, forming the light-absorbing film 15 on the second substrate 3 on the liquid crystal layer 21 side can affect the transverse electric field, disturbing the orientation of liquid crystal molecules of the liquid crystal layer 21. As a result, a desired display may not be able be obtained. Consequently, if the light-absorbing film 15 is a conductor or a semiconductor, as described above, the light-absorbing film 15 is preferably formed on the second substrate 3 on the side opposite to the liquid crystal layer 21.

The semiconductor device 100C is obtained with a known method, and the light-absorbing film 15 is formed on the second substrate 3 on the side opposite to the liquid crystal layer 21 side. Subsequently, with the method described above, the liquid crystal layer 21 is formed, and the liquid crystal display device 500C is obtained with a known method.

As described above, according to embodiments of the present invention, a semiconductor device, a color filter substrate, and a display device where light-induced deterioration of TFT characteristics can be prevented without lowering the aperture ratio of pixels, and a method for manufacturing such a semiconductor device and the like can be provided.

### INDUSTRIAL APPLICABILITY

The present invention is very widely applicable. It can be applied to semiconductor devices having TFTs and to various fields of electronic devices having such a semiconductor device. For example, the present invention can be used for active matrix type liquid crystal display devices and organic EL display devices. Such display devices are applicable, for example, to displays of portable phones and portable game devices, and to monitors of digital cameras. The present invention, therefore, is applicable to any electronic devices with built-in liquid crystal display devices and with built-in organic EL display devices.

### DESCRIPTION OF REFERENCE CHARACTERS

2, 3 insulating substrate
4 gate electrode
6 gate insulating film
8 oxide semiconductor layer
9 etch stopper layer
10 TFT
11a source electrode
11b drain electrode
11s source wiring
13 protective layer
15 light-absorbing film
16 contact hole
17 pixel electrode
21 liquid crystal layer
100A semiconductor device
500A liquid crystal display device

1. A semiconductor device, comprising:
a substrate;
a thin film transistor formed on said substrate;
a light-absorbing film that is formed on said thin film transistor and that absorbs light having a wavelength less than 450 nm; and
a pixel electrode connected to said thin film transistor,
wherein said thin film transistor includes an oxide semiconductor layer,
wherein said light-absorbing film is formed of an oxide containing In, Ga, or Zn, and
wherein said light-absorbing film is formed to cover said thin film transistor when viewed from normal direction to said semiconductor device.

2. The semiconductor device according to claim 1, wherein said light-absorbing film is formed to cover said pixel electrode when viewed from normal direction to said semiconductor device.

3. The semiconductor device according to claim 1, wherein said light-absorbing film is formed of the same oxide of which said oxide semiconductor layer of said thin film transistor is formed.

4. The semiconductor device according to claim 1, wherein said oxide semiconductor layer contains In, Ga, or Zn.

5. The semiconductor device according to claim 1, wherein said light-absorbing film has a thickness of at least 0.1 μm and no greater than 10 μm.

6. A color filter substrate that is a substrate having a color filter formed thereon, comprising:
a light-absorbing film that absorbs light having wavelengths of less than 450 nm and that is provided on said substrate on said color filter side or on said substrate on the side opposite to said color filter side,
wherein said light-absorbing film is an oxide containing In, Ga, or Zn.

7. The color filter substrate according to claim 6, wherein said light-absorbing film has a thickness of at least 0.1 μm and no greater than 10 μm.

8. A display device, comprising:
said color filter substrate according to claim 6; and
a thin film transistor having an oxide semiconductor layer.

9. The display device according to claim 8, wherein said light-absorbing film is formed of the same oxide of which said oxide semiconductor layer of said thin film transistor is formed.

10. A method for manufacturing a semiconductor device, comprising:
a process (A) of preparing a substrate;
a process (B) of forming on said substrate a thin film transistor having an oxide semiconductor layer; and
a process (C) of forming a light-absorbing film that absorbs light having wavelengths of less than 450 nm, such that, when viewed from normal direction to said substrate, said light-absorbing film covers said thin film transistor.

11. The method for manufacturing a semiconductor device according to claim 10, wherein said process (C) includes a process (C1) of forming said light-absorbing film using the oxide film of which said oxide semiconductor layer of said thin film transistor is formed.

12. The method for manufacturing a semiconductor device according to claim 10, wherein said light-absorbing film is an oxide film containing In, Ga, or Zn.

13. The method for manufacturing a semiconductor device according to claim 10, wherein said process (C) includes a process (C2) of forming said light-absorbing film such that said light-absorbing film has a thickness of at least 0.1 μm and no greater than 10 μm.

14. The method for manufacturing a semiconductor device according to claim 10, wherein said process (C) includes a process (C3) of forming said light-absorbing film having insulating properties.

15. The method for manufacturing a semiconductor device according to claim 10, wherein said process (C) includes a process (C4) of forming said light-absorbing film having conductive properties.

16. The display device according to claim 8, wherein said oxide semiconductor layer contains In, Ga, or Zn.

17. The method for manufacturing a semiconductor device according to claim 10, wherein the said oxide semiconductor layer contains In, Ga, or Zn.
